(19) United States
(12) Patent Application Publication
(10) Pub. No.: US 2025/0121588 A1
(43) Pub. Date: Apr. 17, 2025

(54) COMPOSITE DIELECTRIC STRUCTURE IMPLEMENTED WITH HYBRID CERAMIC MATERIAL AND METHOD OF PRODUCING SAME

(71) Applicant: Cyntec Co., Ltd., Hsinchu (TW)

(72) Inventor: Chihung Su, Hsinchu (TW)

(21) Appl. No.: 18/381,100

(22) Filed: Oct. 17, 2023

(51) Int. Cl. B32B 17/06; B32B 7/02; B32B 9/00; C04B 37/00; H05K 9/00

(52) U.S. Cl. CPC B32B 17/06; B32B 7/02; B32B 9/005; C04B 37/003; H05K 9/0088; B32B 2457/00; C04B 2237/10; C04B 2237/708

(57) ABSTRACT

A composite dielectric structure includes a first dielectric ceramic layer including a first dielectric ceramic material and having a first permittivity; a second dielectric ceramic layer including a second dielectric ceramic material and having a second permittivity; and an interleaving layer comprising a glass or glass-based material. A volume percentage of the glass or glass-based material is 93%-100% of overall material of the interleaving layer. The interleaving layer is disposed between a first surface of the first dielectric ceramic layer and a second surface of the second dielectric ceramic layer for binding the first dielectric ceramic layer and the dielectric second surface of the second ceramic layer to form the composite dielectric structure.

### FIELD OF THE INVENTION

The present invention relates to a dielectric structure, and more particular to a composite dielectric structure implemented with a hybrid ceramic material. The present invention also relates a method of producing a composite dielectric structure implemented with a hybrid ceramic material.

### BACKGROUND OF THE INVENTION

With the 5th generation mobile networks or 5th generation wireless systems (hereinafter referred to as 5G) entering people's daily life, the optimization of the design and manufacture of millimeter-wave antenna modules has become an important topic. At present, the globally unified 5G band mainly falls in all or part of the 26 GHz band (24.25 GHz-27.5 GHz), 40 GHz band (37 GHz-43.5 GHz) and 66 GHz-71 GHz band. The 26 GHz band has the advantages of low frequency, large bandwidth and relatively small difficulty in equipment implementation, so it is a hot band that global 5G industries strive to use. Since the 26 GHz band is near the frequency band for satellite earth exploration services, signal interference resulting from near frequency bands may occur and should be filtered out. Therefore, when designing a millimeter-wave antenna module, a high-frequency filter can be used to filter out the signal interference.

However, the dielectric materials for producing an antenna device and a filter device, both included in a millimeter-wave antenna module at the same time, are different. Generally, a Low-K dielectric material is used for producing an antenna device, while a High-K dielectric material is used for producing a filter device for high volume density. If materials with the same or similar permittivity is reluctantly used for producing both devices, problems such as excessive size of the high-frequency filter or excessive energy loss of the high-frequency antenna would occur. Accordingly, how to combine materials with different permittivities would be the technological key for manufacturing a desirable millimeter-wave antenna module.

### SUMMARY OF THE INVENTION

Therefore, the present invention provides a composite dielectric structure, which includes ceramic layers of different dielectric permittivities and is suitable for producing a high-frequency antenna module with a high-frequency filter.

The present invention also provides a method for manufacturing a composite dielectric structure, which conducts cofiring under an atmospheric environment without external pressure to include ceramic layers of different dielectric permittivities.

In an aspect of the present invention, a composite dielectric structure includes a first dielectric ceramic layer including a first dielectric ceramic material and having a first permittivity; a second dielectric ceramic layer including a second dielectric ceramic material and having a second permittivity; and an interleaving layer comprising a glass or glass-based material. A volume percentage of the glass or glass-based material is 93%-100% of overall material of the interleaving layer. The interleaving layer is disposed between a first surface of the first dielectric ceramic layer and a second surface of the second dielectric ceramic layer for binding the first dielectric ceramic layer and the dielectric second surface of the second ceramic layer to form the composite dielectric structure.

In another aspect of the present invention, a method of producing a composite dielectric structure implemented with a hybrid ceramic material includes: providing at least one green sheet of a first dielectric ceramic layer including a first dielectric ceramic material and having a first permittivity; providing at least one green sheet of a second dielectric ceramic layer including a second dielectric ceramic material and having a second permittivity; providing at least one green sheet of an interleaving layer; stacking the at least one green sheet of the interleaving layer between the at least one green sheet of the first dielectric ceramic layer and the at least one green sheet of the second dielectric ceramic layer to form a multiplayer structure, wherein the interleaving layer comprising a glass or glass-based material powders, whose weight percentage is 90%-100% of overall material of green sheet of the interleaving layer; and performing a low-temperature cofiring process of the multilayer structure to form a composite dielectric structure.

By adding materials that can absorb the stress generated when cofiring different heterogeneous ceramics, ideal cofiring matching and reactivity can be achieved, and cracks and defects inside and outside the low-temperature cofired ceramics (LTCC) can thus be reduced.

### BRIEF DESCRIPTION OF THE DRAWINGS

The above contents of the present invention will become more readily apparent to those ordinarily skilled in the art after reviewing the following detailed description and accompanying drawings, in which:

FIG. 1A is a schematic diagram illustrating a composite ceramic structure according to an embodiment of the present invention;

FIG. 1B is a schematic diagram illustrating an example of the composite ceramic structure of FIG. 1A;

FIG. 1C is a schematic diagram illustrating another example of the composite ceramic structure of FIG. 1A;

FIG. 1D is a schematic diagram illustrating a further example of the composite ceramic structure of FIG. 1A;

FIG. 1E is a schematic diagram illustrating yet another example of the composite ceramic structure of FIG. 1A;

FIG. 2 is a cross-sectional diagram schematically illustrating a dielectric ceramic material of the first dielectric ceramic layer, the second dielectric ceramic layer or the interleaving layer after the cofiring process according to an embodiment of the present invention;

FIG. 3A is a schematic diagram illustrating a tape-cast coater adapted to be used for producing green sheets of an interleaving layer, a first dielectric ceramic material layer and a second dielectric ceramic material layer of a composite dielectric structure according to an embodiment of the present invention;

FIG. 3B is a schematic diagram illustrating a slicing process of a green sheet of the interleaving layer, the first dielectric ceramic material layer or the second dielectric ceramic material layer is formed in the process illustrated in FIG. 3A;

FIG. 3C is a schematic diagram illustrating a stacking process of the interleaving layer, a first dielectric ceramic layer and a second dielectric ceramic layer to form a composite dielectric structure; and

FIG. 3D is a schematic diagram illustrating formation of the first dielectric ceramic layer and the second dielectric ceramic layer of FIG. 3C by introducing via patterns or conductive patterns in the first dielectric ceramic material layer or the second dielectric ceramic material layer of FIG. 3B.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

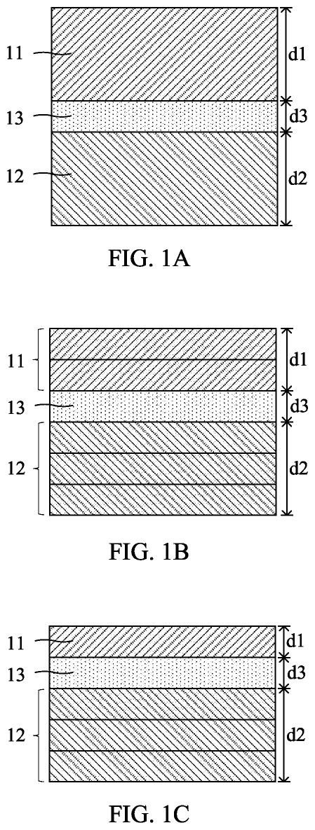

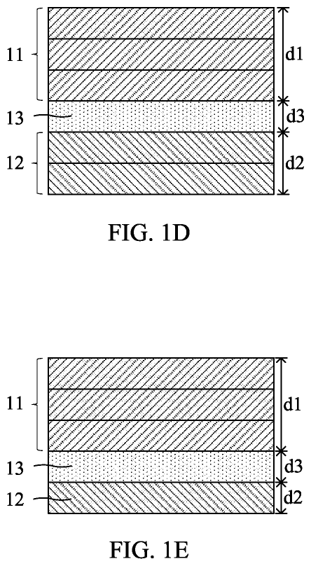

Please refer to FIG. 1A, which schematically illustrates a composite ceramic structure according to an embodiment of the present invention. The composite ceramic structure includes a first dielectric ceramic layer 11 made of a first dielectric ceramic material, a second dielectric ceramic layer 12 made of a second dielectric ceramic material, and an interleaving layer 13. The first dielectric ceramic layer 11 has a first permittivity Dk1 greater than a second permittivity Dk2 of the second dielectric ceramic layer 12. The interleaving layer 13 includes a glass-based material, e.g., glass or complex of glass. The glass-based material occupies 90˜100 wt % of the overall material forming the interleaving layer 13. The interleaving layer 13 is disposed between a first surface of the first dielectric ceramic layer 11 and a second surface of the second dielectric ceramic layer 12, and binds the first dielectric ceramic layer 11 and the second dielectric ceramic layer 12 to form the composite ceramic structure.

In this embodiment, the first dielectric ceramic layer 11 is a high-K dielectric material and has a first permittivity Dk1, also known as dielectric constant, greater than 20 (Dk1>20), e.g., 20.523. In contrast, the second dielectric ceramic layer 12 is a low-K dielectric material and has a second permittivity Dk2 for high volume density, also known as dielectric constant, less than 5 (Dk2<5), e.g., 3.9. In this embodiment, a first ceramic material of the first dielectric ceramic layer 11 and a second ceramic material of the second dielectric ceramic layer 12 are different. When the first dielectric ceramic layer 11 is used as an insulation portion of a filter device, which further includes a conductive structure and may be a multilayer structure, and the second dielectric ceramic layer 12 is used as an insulation portion of an antenna device, which further includes a conductive structure and may also be a multilayer structure, the first permittivity Dk1 is preferably greater than the second permittivity Dk2, and more preferably, Dk1/Dk2 is greater than 4. Under this circumstance, a millimeter-wave antenna module including both the filter device and the antenna device so as to be applicable to the desired band while exempting from signal interference can be produced. The conductive structure included in the filter device or the antenna device may include at least one conductive pattern and at least one via disposed in the insulation portion. In this embodiment, the interleaving layer 13 binds the first dielectric ceramic layer 11 and the second dielectric ceramic layer 12 together by way of a low-temperature cofiring process under a substantially atmospheric pressure so that the filter device and the antenna device can be electrically connected through the via or vias (not shown) disposed in the interleaving layer 13. The third permittivity Dk3 may, for example, be 3.5°

For example, the interleaving layer 13 may be formed of a high-temperature liquid-phase material, which is in a liquid phase instead of a gas phase at a cofiring temperature greater than 100° C., and has a softening point lower than softening points of both the first dielectric ceramic layer 11 and the second dielectric ceramic layer 12. Accordingly, in the low-temperature cofiring process, a variety of stresses, e.g., shrinkage stress and expansion stress generated during the heat-up and cool down processes can be absorbed. The softening point of the interleaving layer 13 may be, for example, 400-600° C., and preferably ranged between 500 and 600° C., which is at least 100° C. lower than each of the softening points of the first dielectric ceramic layer 11 and the second dielectric ceramic layer 12. The first dielectric ceramic layer 11, the interleaving layer 13 and the second dielectric ceramic layer 12 as described above can be bound together by way of a low-temperature cofiring process under a substantially atmospheric pressure to form a composite ceramic structure as desired. In an embodiment, the softening point of the glass-based material of the interleaving layer 13 may be, for example, 400-600° C., and preferably ranged between 500 and 600° C., which is at least 100° C. lower than each of the softening points of ceramic powders of the first dielectric ceramic layer 11 and the second dielectric ceramic layer 12. Since the softening points of the glass-based material of the interleaving layer 13, the first dielectric ceramic layer 11 and the second dielectric ceramic layer 12 are all higher than the soldering temperature, which is generally 270° C., the interleaving layer 13, the first dielectric ceramic layer 11 and the second dielectric ceramic layer 12 would not be adversely softened during the soldering process of the electronic component to be electrically connected to the system PCB.

In an embodiment, the interleaving layer 13 includes a material formed of glass oxide powders. The glass oxide powders are bound to form the green body of the interleaving layer 13 by way of an adhesive and a solvent before the cofiring process. It is to be noted that after the cofiring process, glass oxide powders are softened and fused with softerned ceramic powders so that the resulting interleaving layer 13 contains a ceramic material, whose volume percentage is about 0%˜7% of the interleaving layer. The glass oxide powder may be a glass or a glass-based material selected from a glass material such as SiO₂, B₂O₃, GeO₂ and/or P₂O₅, a glass complex such as SiO₂—B₂O₃—K₂O—HfO, SiO₂—B₂O₃ or a complex of glass and alkali oxide (e.g., potassium oxide and/or sodium oxide), a glass mixture such as a mixture of glass (e.g., phosphate glass) and inorganic oxide (e.g., silicon oxide, aluminum oxide, potassium oxide, sodium oxide and/or boron oxide) and a combination thereof. Preferably, the contents of the glass or a glass-based material in the interleaving layer 13 is more than the contents of the glass or glass-based material in each of the first dielectric ceramic layer 11 and the second dielectric ceramic layer 12. In an embodiment, the volume percentage of the glass or a glass-based material in the second dielectric ceramic layer 12 is higher than the volume percentage of the glass or glass-based material in the first dielectric ceramic layer 11. For example, after cofiring process, the volume percentage of the glass or glass-based material is 93%-100% of overall material of the interleaving layer 13; the volume percentage of the glass or glass-based material is 13%-33% of overall material of the first dielectric ceramic layer 11; and the volume percentage of the glass or glass-based material is 53%-63% of overall material of the second dielectric ceramic layer 12. The third thickness d3 of the interleaving layer 13 is ranged between 30-70 μm, and preferably 40-50 μm, and smaller than the first thickness d1 of the first dielectric ceramic layer 11 and the second thickness d2 of the second dielectric ceramic layer 12 (d3<d1, d3<d2). The low-temperature cofiring process is performed under an atmospheric pressure at 875° C. for 2 hours. The cofiring temperature is higher than the softening point of glass oxide powders of the interleaving layer 13, and lower than the softening point of dielectric ceramic material powders of the first dielectric ceramic layer 11, the second dielectric ceramic layer 12 and the interleaving layer 13. The resulting stack structure as described above can then be integrated into the composite ceramic structure having the desired properties. Before the cofiring process, preferably, the weight percentage of the glass or glass-based material powders (for green sheet) is 90%-100% of overall material of the interleaving layer 13; the weight percentage of the glass or glass-based material powders (for green sheet) is 10%-30% of overall material of the first dielectric ceramic layer 11; and the weight percentage of the glass or glass-based material powders (for green sheet) is 50%-60% of overall material of the second dielectric ceramic layer 12.

Please refer to FIGS. 1B-1E, which schematically illustrate examples of the first thickness d1 of the first dielectric ceramic layer 11, the second thickness d2 of the second dielectric ceramic layer 12 and the third thickness d3 of the interleaving layer 13. In an embodiment, the thickness d1, d2, d3 of the first dielectric ceramic layer 11, the second dielectric ceramic layer 12 and the interleaving layer 13 can be adjusted by stacking a selected number of dielectric layers of equal thickness (d1=d2). The thickness d1 of the first dielectric ceramic layer 11 and the thickness d2 of the second dielectric ceramic layer 12 may be different (d1/d2). Nevertheless, with the interleaving layer 13, the stresses generated in the first dielectric ceramic layer 11 and the second dielectric ceramic layer 12 of different thickness can still be effectively absorbed. In other words, the first dielectric ceramic layer 11 and the second dielectric ceramic layer 12 can be bound together to form the composite ceramic structure for used in a millimeter-wave antenna module.

In the cofired structure of the interleaving layer 13, the first dielectric ceramic layer 11 and the second dielectric ceramic layer 12, all the glass oxide powders are fused together so that grain borders are eliminated. The interleaving layer 13 having a third thickness d3 lying in a preferred range, e.g., 30 μm-70 μm, has improved binding strength and stress-absorbing effect. Under the circumstance, the first thickness d1 of the first dielectric ceramic layer 11 and the second thickness d2 of the second dielectric ceramic layer 12 can be flexibly designed and do not have to approximate each other. The weight percentages of the glass oxide powders, adhesive and solvent are 40-60%, 6-15% and 40-60%, respectively. Subsequently, the adhesive and solvent are burnt or evaporated in the cofiring process, and do not exist in the composite dielectric structure.

Since the first dielectric ceramic layer 11 has a relatively high permittivity and the second dielectric ceramic layer 12 has a relatively low permittivity, the first dielectric ceramic layer 11 is adapted to be used in a filter device, and the second dielectric ceramic layer 12 is adapted to be used in an antenna device. The operating frequency band (frequency zone) of the filter device and the antenna device can be at the 26 GHz zone (24.25 GHz-27.5 GHz), the 40 GHz zone (37 GHz-43.5 GHz) or the 66 GHz-71 GHz zone. In this way, the composite dielectric structure produced according to the present invention can be used to implement the antenna device and the filter device in the same millimeter wave antenna module at the same time as materials of different permittivities are successfully integrated.

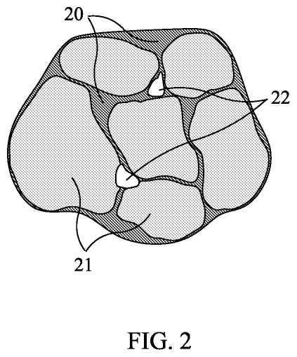

Please refer to FIG. 2, which schematically illustrates a dielectric ceramic material of the first dielectric ceramic layer, the second dielectric ceramic layer or the interleaving layer after the cofiring process according to an embodiment of the present invention. The first dielectric ceramic material and the second dielectric ceramic material may contain, for example, glass and ceramic powders. The ceramic powders in the mixture of the first dielectric ceramic material and/or the second dielectric ceramic material may contain ZrO₂ or ZnO. As shown, in the mixture of the first dielectric ceramic material and/or the second dielectric ceramic material, the glass 20 is formed on at least partial surfaces of the ceramic powders 21, and some voids 22 are present. In an embodiment, the ceramic powders 21 of the first dielectric ceramic material and the second dielectric ceramic material are different. In other words, the ceramic powders 21 are bound with the glass 21 so as to reduce the stress on the ceramic powders 21. Examples of the mixture of glass/ceramic powders include, but are not limited to, SiO2-B2O3-K2O—HfO/ZrO2, SiO2-B2O3-K2O—HfO/ZrO2-Li1+x−yNb1−x−3yTix+4yO3, SiO2-B2O/ZnO—Nb2O5-TiO2, etc.

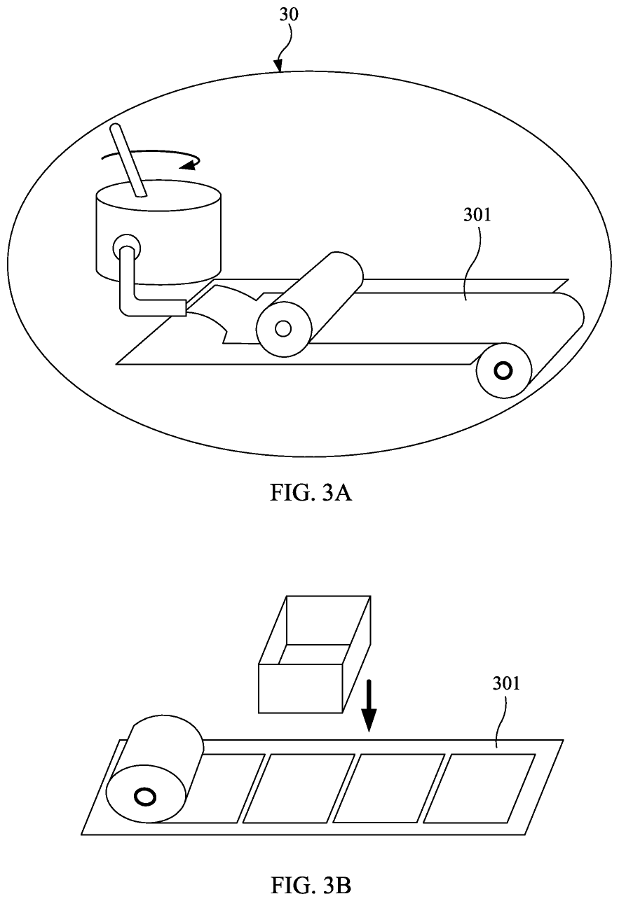

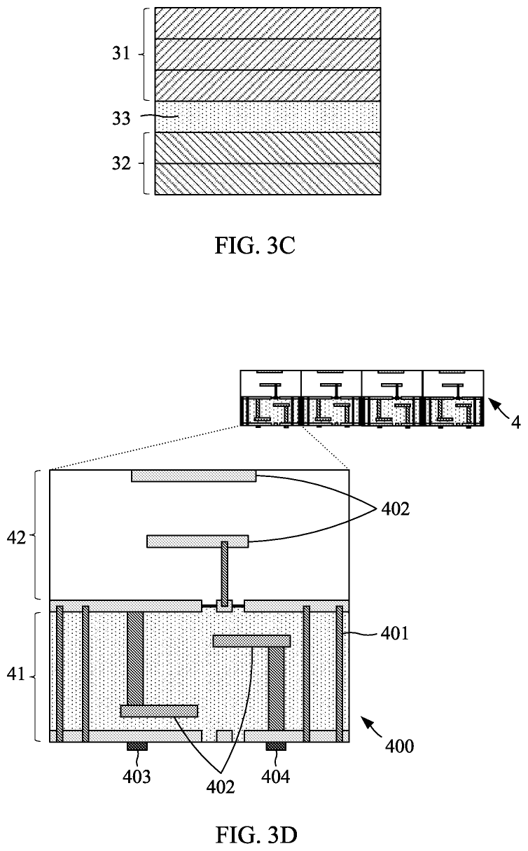

FIGS. 3A, 3B and 3C schematically illustrate a method of producing a composite dielectric structure according to an embodiment of the present invention. Firstly, the raw material powders, e.g., ceramic powders and/or glass or glass-based material powders, are added into a solvent with a dispersant and then optionally ground and dispersed into a powder slurry. Then, the dispersed powder slurry is added into a plasticizer and an adhesive which have been dissolved in a solvent in advance. The mixture is continuously stirred until the components are evenly dispersed. Accordingly, the preparation of green slurry which meets a preset viscosity range is completed. Afterwards, as illustrated in FIG. 3A, the green slurry is poured onto a prepared thin strip 301 in a tape-casting coater 30. The gap parameters of a blade of the tape-casting coater 30 are adjusted to obtain green-ware sheets of an interleaving layer, a first dielectric ceramic material layer and a second dielectric ceramic material layer, each of which has a thickness conforming to a preset thickness range. By selectively using raw materials of different compositions, the properties of the produced interleaving layer and dielectric ceramic material layers can be adjusted.

Further refer to FIG. 3B. The interleaving layer or the dielectric ceramic material layer on the prepared thin strip, i.e., green sheet, 301 is sliced into a proper size. After via patterns 401 and conductive patterns 402 (see FIG. 3D) are respectively formed in the first and second dielectric ceramic material layers 400 to form the dielectric ceramic layers 31 and 32, the dielectric ceramic layers 31 and 32 are stacked onto opposite sides of the interleaving layer 33, thereby forming the multiplayers of the composite dielectric structure for electronic component, module or substrate, as shown in FIG. 3C. Varying with different stack configurations, a variety of components with different thickness and/or different layouts can be obtained. In this embodiment, the first dielectric ceramic layer 31 has a permittivity greater than a permittivity of the second dielectric ceramic layer 32, and a softening point of the interleaving layer 33 is lower than a softening point of each of the first and second dielectric ceramic layers 31 and 32. The electronic component further includes a pair of electrodes 403 and 404 (FIG. 3D), via which the electronic component can be soldered onto and electrically connected with the system PCB.

Please refer to FIG. 3D. Based on the multilayer structure shown in FIG. 3C, a composite dielectric structure 4 integrated therein a plurality of filter circuit 41 and a plurality of antenna layout 42 can be produced after a cofiring process. The composite dielectric structure 4 is then sliced to produce independent millimeter wave antenna modules 400.

As described above, by adding materials capable of absorbing stress generated during cofiring among different heterogeneous ceramics, materials with different permittivities are allowed to be combined. Furthermore, the dielectric ceramic material of high permittivity and the dielectric ceramic material of low permittivity can be cofired under atmospheric environment without an externally applied pressure. Therefore, ideal cofiring matching and reactivity can be obtained, and cracks and defects inside and outside the ceramic body (LTCC) can be reduced during the low-temperature cofiring process.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A composite dielectric structure, comprising:
a first dielectric ceramic layer including a first dielectric ceramic material and having a first permittivity;
a second dielectric ceramic layer including a second dielectric ceramic material and having a second permittivity; and
an interleaving layer comprising a glass or glass-based material, whose volume percentage is 93%-100% of overall material of the interleaving layer, the interleaving layer being disposed between a first surface of the first dielectric ceramic layer and a second surface of the second dielectric ceramic layer and binding the first dielectric ceramic layer and the dielectric second surface of the second ceramic layer to form the composite dielectric structure.

2. The composite dielectric structure according to claim 1, wherein the first permittivity is greater than the second permittivity.

3. The composite dielectric structure according to claim 2, wherein the first permittivity is greater than four times the second permittivity.

4. The composite dielectric structure according to claim 1, wherein the glass or glass-based material of the interleaving layer comprises a high-temperature liquid-phase material having a softening point lower than a softening point of the first dielectric ceramic material and a softening point of the second dielectric ceramic material.

5. The composite dielectric structure according to claim 3, wherein the softening point of the high-temperature liquid-phase material is 400-600° C.

6. The composite dielectric structure according to claim 1, wherein the glass oxide powders are made of a glass or a glass-based material selected from a group consisting of SiO₂, B₂O₃, GeO₂, P₂O₅ and a combination thereof; a glass complex selected from a group consisting of SiO₂—B₂O₃—K₂O—HfO, SiO₂—B₂O₃ and a combination thereof; a complex of glass and alkali oxide, which is selected from a group consisting of potassium oxide, sodium oxide and a combination thereof; or a mixture of glass, which includes phosphate glass, and inorganic oxide, which is selected from a group consisting of silicon oxide, aluminum oxide, potassium oxide, sodium oxide and/or boron oxide.

7. The composite dielectric structure according to claim 1, wherein the interleaving layer further comprises a ceramic material, whose volume percentage is 0%-7% of overall material of the interleaving layer.

8. The composite dielectric structure according to claim 1, wherein a third thickness of the interleaving layer is ranged between 30 μm and 70 μm, and less than a first thickness of the first dielectric ceramic layer and a second thickness of the second dielectric ceramic layer.

9. The composite dielectric structure according to claim 1, wherein a softening point of the glass or glass-based material is ranged between 500° C. and 600° C. and at least 100° C. lower than a softening point of ceramic powders of each of the first dielectric ceramic layer and the second dielectric ceramic layer, and a thickness of the interleaving layer is ranged between 40 μm and 50 μm.

10. The composite dielectric structure according to claim 1, wherein the first dielectric ceramic material and/or the second dielectric ceramic material comprise a mixture of glass or glass-based material and ceramic powders; a volume percentage of the glass or glass-based material in the interleaving layer is higher than a volume percentage of the glass or glass-based material in the mixture of the first dielectric ceramic material and higher than a volume percentage of the glass or glass-based material in the mixture of in the second dielectric ceramic material.

11. The composite dielectric structure according to claim 10, wherein the volume percentage of the glass or glass-based material in the first dielectric ceramic layer is 13%-33%; and the volume percentage of the glass or glass-based material in the second dielectric ceramic layer is 53%-63%.

12. The composite dielectric structure according to claim 10, wherein in the mixture of the first dielectric ceramic material and/or the second dielectric ceramic material, the glass or glass-based material is formed on at least partial surfaces of the ceramic powders; the ceramic powders of the first dielectric ceramic material and the second dielectric ceramic material are different; and the interleaving layer is in direct contact with the first dielectric ceramic layer and the second dielectric ceramic layer.

13. The composite dielectric structure according to claim 1, wherein the first dielectric ceramic layer is disposed in a filter device, and the second dielectric ceramic layer is disposed in an antenna device.

14. The composite dielectric structure according to claim 1, wherein the first dielectric ceramic layer and the second dielectric ceramic layer are stacked with the interleaving layer in a stack direction, and a thickness of the first dielectric ceramic layer and a thickness of the second dielectric ceramic layer are different in the stack direction.

15. A method of producing a composite dielectric structure implemented with a hybrid ceramic material, comprising:
providing at least one green sheet of a first dielectric ceramic layer including a first dielectric ceramic material and having a first permittivity;
providing at least one green sheet of a second dielectric ceramic layer including a second dielectric ceramic material and having a second permittivity;
providing at least one green sheet of an interleaving layer;
stacking the at least one green sheet of the interleaving layer between the at least one green sheet of the first dielectric ceramic layer and the at least one green sheet of the second dielectric ceramic layer to form a multiplayer structure, wherein the interleaving layer comprises glass or glass-based material powders, whose weight percentage is 90%-100% of overall material of the at least one green sheet of the interleaving layer; and
performing a low-temperature cofiring process of the multilayer structure to form a composite dielectric structure.

16. The method according to claim 15, wherein the at least one green sheet of the first or second dielectric ceramic layer is formed by mixing ceramic powders, a solvent and an adhesive, wherein a third thickness of the interleaving layer is smaller than a first thickness of the first dielectric ceramic layer and smaller than a second thickness of the first dielectric ceramic layer.

17. The method according to claim 15, wherein the first permittivity is greater than the second permittivity.

18. The method according to claim 17, wherein the first permittivity is greater than four times the second permittivity.

19. The method according to claim 15, wherein the interleaving layer comprises a high-temperature liquid-phase material having a softening point lower than a softening point of the first dielectric ceramic material and a softening point of the second dielectric ceramic material.

20. The method according to claim 15, wherein the softening point of the high-temperature liquid-phase material is 400-600° C.

21. The method according to claim 15, wherein the glass or glass-based material powders are selected from a group consisting of alkali oxides, an inorganic glass mixture and a combination thereof.

22. The method according to claim 21, wherein the inorganic oxide mixture includes a mixture of phosphate glass, silicon oxide, aluminum oxide, potassium oxide, sodium oxide and boron oxide; the thickness of the at least one green sheet of the interleaving layer is ranged between 40 μm and 50 μm; and the softening point of glass or glass-based material powders of the at least one green sheet of the interleaving layer is ranged between 500° C. and 600° C. and at least 100° C. lower than a softening point of each of the first dielectric ceramic layer and the second dielectric ceramic layer.

23. The method according to claim 15, wherein the material of the at east one green sheet of the interleaving layer further includes an adhesive and a solvent, and weight percentages of the glass or glass-based material powders, the adhesive and the solvent are 40-60%, 6-15% and 40-60%, respectively.

24. The method according to claim 15, wherein the first dielectric ceramic material and/or the second dielectric ceramic material comprise a mixture of glass or glass-based material powders and ceramic powders;
a weight percentage of the glass or a glass-based material powders in the green sheet of the interleaving layer is higher than a weight percentage of the glass or glass-based material powders in the mixture of the first dielectric ceramic material and higher than a weight percentage of the glass or glass-based material powders in the mixture of in the second dielectric ceramic material.

25. The method according to claim 15, wherein the material of the at least one green sheet of the interleaving layer comprises 93-100 vol % glass or glass-based material powders and 5˜7 vol % ceramic powders; the first dielectric ceramic material and/or the second dielectric ceramic material comprise a mixture of glass or glass-based material powders and ceramic powders; a weight percentage of the glass or glass-based material powders in the at least one green sheet of the interleaving layer is 90%-100%; a weight percentage of the glass or glass-based material powders in the at least one green sheet of the first dielectric ceramic layer is 10%-30%; and a weight percentage of the glass or glass-based material powders in the at least one green sheet of the second dielectric ceramic layer is 50%-60%.

26. The method according to claim 15, wherein the at least one green sheet of the first dielectric ceramic layer and the at least one green sheet of the second dielectric ceramic layer are stacked with the at least one green sheet of the interleaving layer in a stack direction, and a first thickness of the at least one green sheet of the first dielectric ceramic layer and a second thickness of the at least one green sheet of the second dielectric ceramic layer are different in the stack direction.
